(19) United States
(12) Patent Application Publication
(10) Pub. No.: US 2022/0231103 A1
(43) Pub. Date: Jul. 21, 2022

(54) DISPLAY SUBSTRATE AND METHOD FOR MANUFACTURING SAME, AND DISPLAY DEVICE

(71) Applicants: MIANYANG BOE OPTOELECTRONICS TECHNOLOGY CO., Ltd., Mianyang (CN); BOE Technology Group Co., Ltd., Beijing (CN)

(72) Inventors: Yaojin YIN, Beijing (CN); Qinglin MA, Beijing (CN); Chao QI, Beijing (CN); Yuxi LIU, Beijing (CN); Zhenyu SUN, Beijing (CN)

(21) Appl. No.: 17/508,939

(22) Filed: Oct. 22, 2021

(30) Foreign Application Priority Data
Jan. 19, 2021 (CN) 202110071115.X

(51) Int. Cl. H01L 27/32; H01L 51/52; H01L 51/56

(52) U.S. Cl. CPC H01L 27/3262; H01L 27/3276; H01L 51/56; H01L 51/5237

(57) ABSTRACT

A display substrate is provided. The display substrate includes a display region and a non-display region surrounding the display region. A portion, in the non-display region, of the display substrate includes: a base, a first material layer disposed on a side of the base, and a second material layer disposed on a side of the first material layer away from the base. The first material layer includes a first portion and a plurality of second portions, a thickness of the first portion is less than a thickness of the second portion, a first portion is disposed between any two adjacent second portions, and the second material layer covers the first material layer.

### CROSS-REFERENCE TO RELATED APPLICATION

This application claims priority to Chinese Patent Application No. 202110071115.X, filed on Jan. 19, 2021 and entitled “DISPLAY SUBSTRATE AND METHOD FOR MANUFACTURING SAME, AND DISPLAY DEVICE”, the entire content of which is incorporated herein by reference.

### TECHNICAL FIELD

The present disclosure relates to the field of display technologies, and in particular to a display substrate and a method for manufacturing the same, and a display device.

### BACKGROUND

Organic light-emitting diode (OLED) display substrates are widely used for their characteristics of self-luminance, wide viewing angle, wide color gamut, high contrast, low power consumption, fast response speed and the like.

In the related art, an OLED display substrate has a display region and a non-display region. The OLED display substrate includes a plurality of sub-pixels in the display region and an encapsulation film layer encapsulating the plurality of sub-pixels. The design of the encapsulation film layer can ensure the encapsulation performance of the OLED display substrate and improve the yield of the OLED display substrate.

### SUMMARY

The present disclosure provides a display substrate and a method for manufacturing the same, and a display device. The technical solutions are as follows.

In an aspect, a display substrate is provided. The display substrate includes a display region and a non-display region surrounding the display region, wherein a portion, in the non-display region, of the display substrate includes: a base; a first material layer disposed on a side of the base, wherein the first material layer includes a first portion and a plurality of second portions, a thickness of the first portion being less than a thickness of the second portion, and the first portion being disposed between any adjacent two second portions; and a second material layer disposed on a side of the first material layer away from the base, wherein the second material layer covers the first material layer.

Optionally, the thickness of the first portion is 0.

Optionally, materials of the first material layer and the second material layer are both conductive materials.

Optionally, the first material layer and a gate of a thin film transistor of a sub-pixel, in the display region, of the display substrate are disposed in a same layer; and the second material layer and an anode of the sub-pixel, in the display region, of the display substrate are disposed in a same layer.

Optionally, the first material layer and a source-drain of a thin film transistor of a sub-pixel, in the display region, of the display substrate are disposed in a same layer; and the second material layer and an anode of the sub-pixel, in the display region, of the display substrate are disposed in a same layer.

Optionally, a common ground terminal voltage circuit trace, in the non-display region, of the display substrate includes the first material layer and the second material layer.

Optionally, the first material layer includes a titanium layer, an aluminum layer, and another titanium layer which are sequentially laminated in a direction going away from the base.

Optionally, the first material layer includes a molybdenum layer, an aluminum layer, and another molybdenum layer which are sequentially laminated in a direction going away from the base.

Optionally, a surface of the second material layer away from the first material layer is parallel to a bearing surface of the base.

Optionally, a shape of an orthographic projection of the second portion on the base is a rectangle.

Optionally, orthographic projections of the plurality of second portions on the base are uniformly arranged in an array.

Optionally, the plurality of second portions are uniformly arranged sequentially in a target direction, and the target direction is a pixel row direction or a pixel column direction of the display substrate.

Optionally, for each of the second portions, an area of an orthographic projection of a surface, away from the base, of the second portion on the base is less than an area of an orthographic projection of a surface, close to the base, of the second portion on the base.

Optionally, the orthographic projection of the surface, away from the base, of the second portion on the base is within the orthographic projection of the surface, close to the base, of the second portion on the base.

Optionally, the display substrate further includes: a third material layer and an encapsulation film layer which are disposed on a side of the second material layer away from the first material layer.

Optionally, the third material layer is a cathode layer of a sub-pixel of the display substrate.

In another aspect, a method for manufacturing a display substrate is provided. The display substrate includes a display region and a non-display region surrounding the display region, and the method includes: forming a first material layer on a side of a base, wherein the first material layer includes a first portion and a plurality of second portions, a thickness of the first portion being less than a thickness of the second portion, and the first portion being disposed between any adjacent two second portions; and forming a second material layer on a side of the first material layer away from the base, wherein the second material layer covers the first material layer.

Optionally, forming the first material layer on the side of the base includes: forming a first material film on the side of the base; and patterning the first material film to obtain the first material layer.

Optionally, the thickness of the first portion is 0.

In yet another aspect, a display device is provided. The display device includes a power supply component and a display substrate connected to the power supply component, wherein the power supply component is configured to supply power to the display substrate; and the display substrate includes a display region and a non-display region surrounding the display region, and a portion, in the non-display region, of the display substrate includes: a base; a first material layer disposed on a side of the base, wherein the first material layer includes a first portion and a plurality of second portions, a thickness of the first portion being less than a thickness of the second portion, and the first portion being disposed between any adjacent two second portions; and a second material layer disposed on a side of the first material layer away from the base, wherein the second material layer covers the first material layer.

### BRIEF DESCRIPTION OF THE DRAWINGS

To describe the technical solutions in embodiments of the present disclosure or prior art more clearly, the following briefly introduces the accompanying drawings required for describing the embodiments or the prior art. Apparently, the accompanying drawings in the following description show merely some embodiments of the present disclosure, and persons of ordinary skill in the art may still derive other drawings from these accompanying drawings without creative efforts.

FIG. 1 is a schematic structural diagram of a non-display region of a display substrate in the related art;

FIG. 2 is a top view of a display substrate according to an embodiment of the present disclosure;

FIG. 3 is a schematic structural diagram of a non-display region of a display substrate according to an embodiment of the present disclosure;

FIG. 4 is a schematic structural diagram of a base and a first material layer, in a non-display region, of a display substrate according to an embodiment of the present disclosure;

FIG. 5 is a schematic structural diagram of a non-display region of another display substrate according to an embodiment of the present disclosure;

FIG. 6 is a top view of a non-display region of a display substrate according to an embodiment of the present disclosure;

FIG. 7 is a top view of a non-display region of another display substrate according to an embodiment of the present disclosure;

FIG. 8 is a schematic structural diagram of a non-display region of yet another display substrate according to an embodiment of the present disclosure;

FIG. 9 is a top view of another display substrate according to an embodiment of the present disclosure;

FIG. 10 is a schematic structural diagram of a non-display region of still a further display substrate according to an embodiment of the present disclosure;

FIG. 11 is a flowchart of a method for manufacturing a display substrate according to an embodiment of the present disclosure;

FIG. 12 is a flowchart of another method for manufacturing a display substrate according to an embodiment of the present disclosure; and

FIG. 13 is a schematic structural diagram of a display device according to an embodiment of the present disclosure.

### DETAILED DESCRIPTION

The technical solutions in the embodiments of the present disclosure will be clearly and completely described below in combination with the accompanying drawings in the embodiments of the present disclosure. Apparently, the described embodiments are only part but not all of the embodiments of the present disclosure. All other embodiments derived by persons of ordinary skill in the art without creative efforts based on the embodiments in the present disclosure are within the protection scope of the present disclosure.

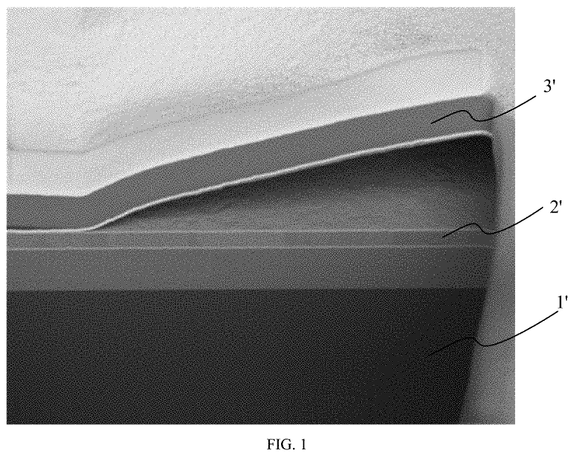

In the related art, referring to FIG. 1, the portion, in a non-display region, of an OLED display substrate includes a base 1′, and a first material layer 2′ and a second material layer 3′ which are laminated in sequence on a side of the base 1′. If the preparation accuracy of the first material layer 2′ and the second material layer 3′ is low (for example, an interface between the first material layer 2′ and the second material layer 3′ is not smooth and uneven), peeling may occur between the first material layer 2′ and the second material layer 3′. As a result, a water and oxygen path may be formed at the interface between the first material layer 2′ and the second material layer 3′, and the OLED display substrate has poor encapsulation performance in the non-display region, resulting in grow dark spots (GDS).

When the OLED display substrate is applied to a display device, a dark spot appears at the position of the grow dark spot of the display substrate when the display device displays an image. That is, the grow dark spots generated by the OLED display substrate cause the display device to fail, and the yield of the display device is low.

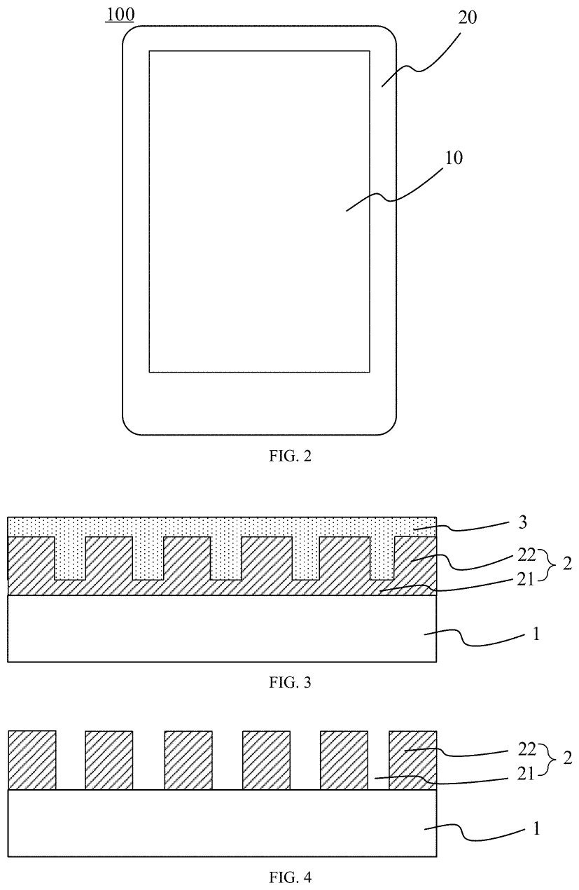

FIG. 2 is a top view of a display substrate according to an embodiment of the present disclosure. Referring to FIG. 2, it can be seen that the display substrate 100 may include a display region 10 and a non-display region 20 surrounding the display region 10. FIG. 3 is a schematic structural diagram of a portion, in a non-display region, of a display substrate according to an embodiment of the present disclosure. Referring to FIG. 3, it can be seen that the portion, in the non-display region 20, of the display substrate 100 may include: a base 1, a first material layer 2 and a second material layer 3.

The first material layer 2 is disposed on a side of the base 1. The second material layer 3 is disposed on a side of the first material layer 2 away from the base 1, and the second material layer 3 covers the first material layer 2. That is, the base 1, the first material layer 2 and the second material 3 are laminated in sequence.

In the embodiment of the present disclosure, the first material layer 2 being disposed on a side of the base 1 refers to that an overall pattern layer of the first material layer 2 is disposed on a side of the base 1, instead of indicating an absolute positional relationship of partial structures. The positional relationship between other pattern layers is similar to the above, and details are not repeated here.

Referring to FIG. 3, it can be seen that the first material layer 2 may include a first portion 21 and a plurality of second portions 22. The thickness of the first portion 21 is less than the thickness of the second portion 22, and the first portion 21 is disposed between any adjacent two second portions 22.

Here, the second material layer 3 covering the first material layer 2 refers to that the second material layer 3 covers the first portion 21 and the plurality of second portions 22 of the first material layer 2, and the second material layer 3 may fill a target region. The target region is formed by adjacent side faces of two adjacent second portions 22 and the face of the first portion 21 close to the second material layer 3.

The second material layer 3 is in contact with not only the side of the second portion 22 close to the second material layer 3 and the side of the first portion 21 close to the second material layer 3, but also the sidewall of the second portion 22. Therefore, the contact area and the bonding force between the first material layer 2 and the second material layer 3 are increased, so that the first material layer 2 and the second material layer 3 are not easily peeled from each other. Further, the water and oxygen path at the interface between the first material layer 2 and the second material layer 3 can be prevented from forming, thereby preventing grow dark spots from generating on the display substrate, and ensuring the display effect of the display device.

In summary, the embodiment of the present disclosure provides a display substrate. The thickness of the first portion of the first material layer in the non-display region of the display substrate is less than the thickness of the second portion, so that the second material layer is in contact with the sidewall of the second portion. Therefore, the contact area and the bonding force between the second material layer and the first material layer can be increased, and the first material layer and the second material layer are prevented from peeling from each other. Further, the water and oxygen path at the interface between the first material layer and the second material layer can be prevented from forming, thereby preventing grow dark spots from generating on the display substrate, and ensuring the yield and display effect of the display device.

Optionally, the base 1 may be a flexible base. For example, the material of the base 1 may be polyimide (PI), so that the base 1 can be bent or bent to a specific angle according to actual requirements. Therefore, the display substrate 100 is a flexible display substrate or a curved display substrate. Certainly, the base 1 may also be made of other materials (for example, the base 1 may be a rigid base), which is not limited in the embodiment of the present disclosure.

In the case that the base 1 is a flexible base, the base 1 may include a first organic flexible layer, a second organic flexible layer, and an inorganic barrier layer disposed between the first organic flexible layer and the second organic flexible layer. The materials of the first organic flexible layer and the second organic flexible layer include polyimide, and the material of the inorganic barrier layer includes at least one of silicon nitride and silicon oxide. In such a design, not only the toughness of the base 1 can be improved, but also the encapsulation performance of the display substrate 100 is improved.

Optionally, the thickness of the first portion 21 may be 0. That is, referring to FIG. 4, the first portion 21 may be a gap. Alternatively, the thickness of the first portion 21 is greater than 0. That is, referring to FIG. 3, the first portion 21 may be a groove relative to the second portion 22.

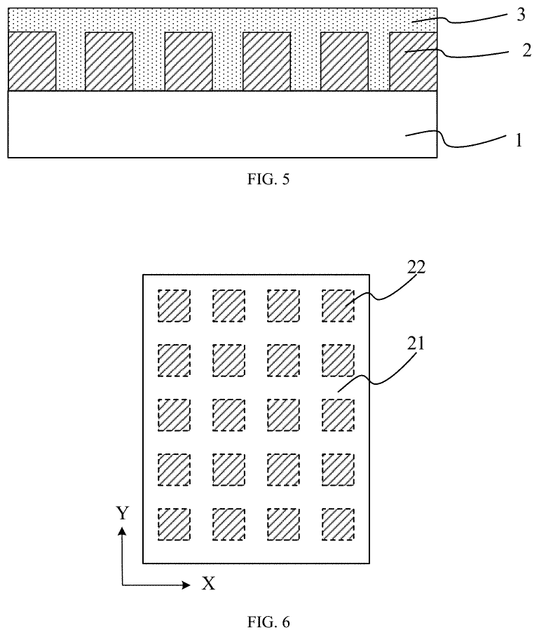

Referring to FIG. 5, in the case that the first portion 21 is a gap, the second material layer 3 covering the first material layer 2 refers to that the second material layer 3 covers the plurality of second portions 22 of the first material layer 2 and fills the gaps. Referring to FIG. 3, in the case that the first portion 21 is a groove relative to the second portion 22, the second material layer 3 covering the first material layer 2 refers to that the second material layer 3 covers the plurality of second portions 22 of the first material layer 2 and fills the grooves.

As shown in FIG. 3 to FIG. 5, the first material layer 2 includes the plurality of second portions 22, and a first portion 21 is disposed between any two adjacent second portions 22. Therefore, the plurality of second portions 22 are disposed to form the plurality of first portions 21 (gaps or grooves). The second material layer 3 covers the first material layer 2 and fills the target region.

In the embodiment of the present disclosure, the manufacturing process of the first material layer 2 may include: forming a first material film on a side of the base 1, and patterning the first material film to acquire the first material layer 2. The patterning treatment may include: photoresist coating, exposure, development, etching, and photoresist removal.

The thickness of the first portion 21 of the first material layer 2 is controlled by controlling the etching duration. The thickness of the first portion 21 is negatively correlated to the etching duration. That is, the longer the etching duration is, the less the thickness of the first portion 21 is; and the shorter the etching duration is, the greater the thickness of the first portion 21 is.

In addition, in order to facilitate the design and manufacture of a mask used during exposure, the sizes of the plurality of second portions 22 may be the same. When there are a large number of the second portions 22, the size of the second portion 22 is small, so that the first material layer 2 can include more first portions 21, and the contact area and the bonding force between the second material layer 3 and the first material layer 2 are increased. Therefore, the number and size of the second portions 22 and the width of the first portion 21 between any two adjacent second portions 22 can be determined according to an actual situation, which is not limited in the embodiment of the present disclosure.

In the embodiment of the present disclosure, the materials of the first material layer 2 and the second material layer 3 may both be conductive materials. Certainly, the first material layer 2 and the second material layer 3 may also be made of other materials as long as the first material layer 2 and the second material layer 3 are adjacent to each other.

In the embodiment of the present disclosure, the portion, in the display region 10, of the display substrate 100 includes the base 1 and a plurality of sub-pixels disposed on a side of the base 1. Each sub-pixel may include a pixel circuit and a light-emitting unit. The pixel circuit may include at least one thin film transistor. The thin film transistor may include a gate, a source, and a drain. The light-emitting unit may include an anode layer, a light-emitting layer and a cathode layer, and the anode layer may be electrically connected to the drain.

Optionally, film layers of the plurality of sub-pixels include a first inorganic layer, a first metal layer, an insulating layer, a second metal layer, a second inorganic layer, an anode layer, a light-emitting layer and a cathode layer which are sequentially laminated in a direction going away from the base 1. The first metal layer may include the gate of the thin film transistor, and the second metal layer may include the source and the drain of the thin film transistor.

In the embodiment of the present disclosure, the first material layer 2 may be disposed in the same layer as the gate of the thin film transistor of the sub-pixel, in the display region 10, of the display substrate 100. The second material layer 3 may be disposed in the same layer as the anode layer of the sub-pixel, in the display region 10, of the display substrate 100. That is, the first material layer 2 and the gate of the thin film transistor of the sub-pixel of the display substrate 100 in the display region 100 may be prepared from the same material by the same mask patterning process. The second material layer 3 and the anode layer of the sub-pixel of the display substrate 100 in the display region 10 may be prepared from the same material by the same mask patterning process.

Alternatively, the first material layer 2 may be disposed in the same layer as the source and the drain of the thin film transistor of the sub-pixel, in the display region 10, of the display substrate 100. The second material layer 3 may be disposed in the same layer as the anode layer of the sub-pixel, in the display region 10, of the display substrate 100. That is, the first material layer 2 and the source and the drain of the thin film transistor of the sub-pixel of the display substrate 100 in the display region 10 may be prepared from the same material by the same mask patterning process. The second material layer 3 and the anode layer of the sub-pixel of the display substrate 100 in the display region 10 may be prepared from the same material by the same mask patterning process.

It should be noted that since the source and the drain of the thin film transistor of the sub-pixel in the display region 10 are disposed in the same layer as a data line in the display region 10, in the case that the first material layer 2 is disposed in the same layer as the source and the drain, the first material layer 2 and the data line are also disposed in the same layer. That is, the first material layer 2, the source and the drain, and the data line are prepared from the same material by the same mask patterning process.

In addition, the second material layer 3 is disposed in the same layer as the anode layer of the sub-pixel, in the display region 10, of the display substrate 100, and the material of the anode layer of the sub-pixel may generally be indium tin oxide (ITO). Therefore, the material of the second material layer 3 may also be ITO. Certainly, the second material layer 3 and the anode layer of the sub-pixel may also be made of other materials, which is not limited in the embodiment of the present disclosure.

Optionally, the first material layer 2 may include a titanium layer, an aluminum layer, and another titanium layer which are sequentially laminated in a direction going away from the base 1. Alternatively, the first material layer 2 may include a molybdenum layer, an aluminum layer, and another molybdenum layer which are sequentially laminated in the direction going away from the base 1. That is, the first material layer 2 may be a laminated structure of titanium, aluminum and titanium or of molybdenum, aluminum and molybdenum. Of course, the first material layer 2 may also be made of other materials, which is not limited in the embodiment of the present disclosure.

In the embodiment of the present disclosure, the shape of the orthographic projection of the second portion 22 on the base 1 may be a rectangle. Alternatively, the shape of the orthographic projection of the second portion 22 on the base 1 may be a circle. In the case that the shape of the orthographic projection of the second portion 22 on the base 1 is a rectangle, the shape of the second portion 22 may be a cube. In the case that the shape of the orthographic projection of the second portion 22 on the base 1 is a circle, the shape of the second portion 22 may be a cylinder.

Of course, the second portion 22 may also be of other shapes. For example, the shape of the second portion 22 is a triangular prism, and the like, which is not limited in the embodiment of the present disclosure. In the case that the shape of the second portion 22 is a triangular prism, the shape of the orthographic projection of the second portion 22 on the base may be a triangle.

In the embodiment of the present disclosure, the plurality of second portions 22 included in the first material layer 2 may be arranged in a plurality of ways.

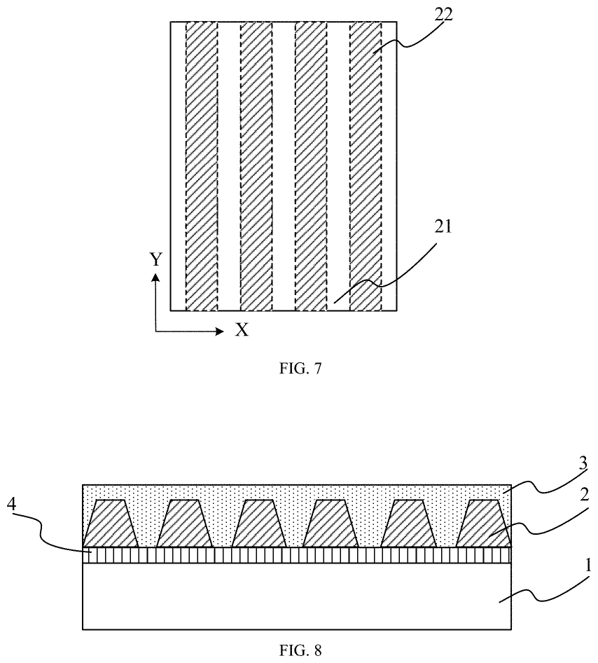

As an optional implementation, referring to FIG. 6, the orthographic projections of the plurality of second portions 22 on the base 1 are uniformly arranged in an array. That is, a plurality of second portions 22 are disposed in both the pixel row direction X and the pixel column direction Y of the display substrate 100, and each second portion 22 has at least two other adjacent second portions 22. Each second portion 22 corresponds to at least two first portions 21, such that the contact area and the bonding force between the first material layer 2 and the second material layer 3 are further increased.

Optionally, in the case that the orthographic projections of the plurality of second portions 22 on the base 1 are uniformly arranged in an array, the at least two first portions 21 corresponding to each second portion 22 may be connected, that is, the first portions 21 may be a whole.

As another optional implementation, the plurality of second portions 22 may be uniformly arranged in sequence in a target direction. The target direction may be the pixel row direction X or the pixel column direction Y of the display substrate.

Optionally, referring to FIG. 7, in the case that the plurality of second portions 22 are arranged in the pixel row direction X, one second portion 22 is disposed in the pixel column direction Y, and a plurality of second portions 22 are disposed in the pixel row direction X. Of course, when the plurality of second portions 22 are arranged in the pixel column direction Y, there is one second portion 22 in the pixel row direction X, and a plurality of second portions 22 are disposed in the pixel column direction Y.

In the embodiment of the present disclosure, for each second portion 22, the area of the orthographic projection of the surface of the second portion 22 away from the base 1 on the base 1 may be less than the area of the orthographic projection of the surface of the second portion 22 close to the base 1 on the base 1. In addition, the orthographic projection of the surface of the second portion 22 away from the base 1 on the base 1 may be within the orthographic projection of the surface of the second portion 22 close to the base 1 on the base 1.

As shown in FIG. 8, the shape of the second portion 22 may be a quadrangular frustum, and the top surface of the quadrangular frustum is parallel to the bearing surface of the base 1. The area of the top surface of the quadrangular frustum is less than the area of the bottom surface of the quadrangular frustum, to facilitate the processing of the first material layer 2. In addition, the shape of the second portion 22 is a quadrangular frustum, such that the area of the side surface of the second portion 22 can be increased, which can further increase the contact area and the bonding force between the first material layer 2 and the second material layer 3.

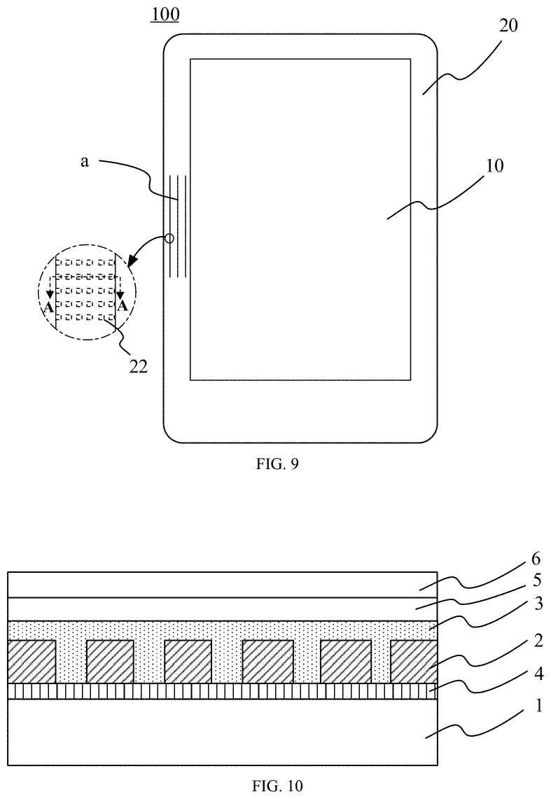

FIG. 9 is a top view of another display substrate according to an embodiment of the present disclosure. Referring to FIG. 9, the portion, in the non-display region 20, of the display substrate 100 may include a common ground terminal voltage (voltage series, (VSS)) circuit trace a. The common ground terminal voltage circuit trace a may include the first material layer 2 and the second material layer 3. That is, the first material layer 2 and the second material layer 3 may serve as the common ground terminal voltage circuit traces a to provide common ground terminal voltage signals for the cathode layer of the sub-pixel. Optionally, FIG. 3, FIG. 5, and FIG. 8 may be all cross-sectional views of FIG. 9 in the AA direction.

Only three common ground terminal voltage circuit traces a are drawn in the non-display region on the left side of the display region 10 in FIG. 9. In practice, the common ground terminal voltage circuit traces a may be disposed in all of the non-display region on the upper side of the display region 10, the non-display region on the right side of the display region 10, and the non-display region on the lower side of the display region 10. In addition, only one common ground terminal voltage circuit trace may be disposed in the non-display region on each side of the display region 10. The position and number of the common ground terminal voltage circuit trace a are not limited in the embodiment of the present disclosure, as long as the common ground terminal voltage circuit trace a can provide the signal for the cathode layer of the sub-pixel.

In the embodiment of the present disclosure, referring to FIG. 8, the portion, in the non-display region 20, of the display substrate 100 further includes an inorganic film layer 4 disposed between the first material layer 2 and the base 1. In addition, referring to FIG. 10, the portion, in the non-display region 20, of the display substrate 100 further includes: a third material layer 5 and an encapsulation film layer 6 which are disposed on the side of the second material layer 3 away from the first material layer 2. The encapsulation film layer 6 may be configured to prevent water vapor from entering the display region of the display substrate 100, to enhance the encapsulation performance of the display substrate 100.

Optionally, the inorganic film layer 4 may be a first inorganic layer, an insulating layer, and a second inorganic layer in the display region 10 of the display substrate 100. That is, the first inorganic layer, the insulating layer, and the second inorganic layer may be disposed in the non-display region 20 in addition to the display region 10.

In addition, the third material layer 5 may be formed into a film by an evaporation process. The film formation by the evaporation process refers to that an evaporation material is heated under a certain vacuum condition, so that the evaporation material is melt or sublimed into vapor composed of atoms, molecules or groups of atoms, and the vapor is then condensed on the surface of the base 1 to form the film. During the evaporation process, the evaporation material is basically formed into the film in a direction perpendicular to the bearing surface of the base 1. The third material layer 5 may be formed by evaporation in a large are, or may be formed by patterning evaporation with a mask.

Optionally, the third material layer 5 may be the cathode layer of the sub-pixel of the display substrate 100. That is, the cathode layer of the sub-pixel may be disposed in the non-display region 20 in addition to the display region 10. In addition, the third material layer 5 is in contact with the second material layer 3, so that the first material layer 2 and the second material layer 3 which serve as the common ground terminal voltage circuit traces a can provide the common ground terminal voltage signals for the third material layer 5 (the cathode layer).

In summary, the embodiment of the present disclosure provides a display substrate. The thickness of the first portion of the first material layer in the non-display region of the display substrate is less than the thickness of the second portion, so that the second material layer is in contact with the sidewall of the second portion. Therefore, the contact area and the bonding force between the second material layer and the first material layer can be increased, to prevent the first material layer and the second material layer from peeling off each other. Further, a water and oxygen path can be prevented from forming at the interface between the first material layer and the second material layer, thereby preventing grow dark spots from generating on the display substrate, and ensuring the yield and display effect of the display device.

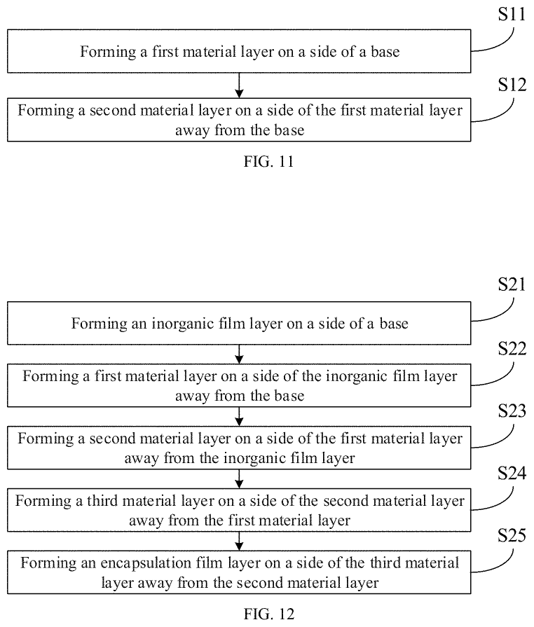

FIG. 11 is a flowchart of a method for manufacturing a display substrate according to an embodiment of the present disclosure. Referring to FIG. 11, the method may include the following steps.

In step S11, a first material layer is formed on a side of a base.

In the embodiment of the present disclosure, after the base 1 is acquired, the first material layer 2 may be formed on a side of the base 1. The first material layer 2 may include a first portion 21 and a plurality of second portions 22. The thickness of the first portion 21 is less than the thickness of the second portion 22, and a first portion 21 is disposed between any two adjacent second portions 22.

In step S12, a second material layer is formed on a side of the first material layer away from the base.

In the embodiment of the present disclosure, after the first material layer 2 is formed, the second material layer 3 may be formed on the side of the first material layer 2 away from the base 1. The second material layer 3 may cover the first material layer 2.

In addition, covering the first material layer 2 by the second material layer 3 refers to that the second material layer 3 covers the first portion 21 and the plurality of second portions 22 of the first material layer 2, and the second material layer 3 can fill the target region.

The second material layer 3 is in contact with not only the side of the second portion 22 close to the second material layer 3 and the side of the first portion 21 close to the second material layer 3, but also the sidewall of the second portion 22. Therefore, the contact area and the bonding force between the first material layer 2 and the second material layer 3 are increased, so that the first material layer 2 and the second material layer 3 are not easily peeled off. Further, a water and oxygen path can be prevented from forming at the interface between the first material layer 2 and the second material layer 3, thereby preventing grow dark spots from generating on the display substrate, and ensuring the display effect of the display device.

In summary, the embodiment of the present disclosure provides a method for manufacturing a display substrate. The thickness of the first portion of the first material layer in the non-display region of the display substrate manufactured by the method is less than the thickness of the second portion, so that the second material layer is in contact with the sidewall of the second portion. Therefore, the contact area and the bonding force between the second material layer and the first material layer can be increased, and the first material layer and the second material layer are prevented from peeling off. Further, the water and oxygen path can be prevented from forming at the interface between the first material layer and the second material layer, thereby preventing grow dark spots from generating on the display substrate, and ensuring the yield and display effect of the display device.

FIG. 12 is a flowchart of another method for manufacturing a display substrate according to an embodiment of the present disclosure. Referring to FIG. 12, the method may include the following steps.

In step S21, an inorganic film layer is formed on a side of a base.

In the embodiment of the present disclosure, the base 1 may be acquired at first, and the inorganic film layer 4 may be formed on a side of the base 1. The inorganic film layer 4 may be formed in a process of forming the sub-pixel of the display substrate. The inorganic film layer 4 may include a portion disposed in the display region and a portion in the non-display region.

Optionally, the base 1 may be a flexible base or a rigid base. In the case that the base 1 is a flexible base, the flexible base is formed on a glass substrate before the display substrate is formed. The glass substrate plays a supporting role in the manufacturing process of the display substrate. After the display substrate is manufactured, the glass substrate and the flexible base also need to be peeled off, to support flexible characteristics of the display substrate.

In step S22, a first material layer is formed on a side of the inorganic film layer away from the base.

In the embodiment of the present disclosure, the process of forming the first material layer 2 may include: forming a first material film on a side of the base 1, and patterning the first material film to acquire the first material layer 2. The patterning treatment may include: photoresist coating, exposure, development, etching, and photoresist removal. The thickness of the first portion 21 of the first material layer 2 is controlled by controlling etching duration.

Optionally, the first material film may be formed through a sputtering process, and the first material film may be etched through dry etching to form the first material layer 2.

The first material layer 2 may include the first portion 21 and the plurality of second portions 22. The thickness of the first portion 21 is less than the thickness of the second portion 22, and a first portion 21 is disposed between any two adjacent second portions 22.

In step S23, a second material layer is formed on a side of the first material layer away from the inorganic film layer.

In the embodiment of the present disclosure, after the first material layer 2 is formed, the second material layer 3 may be formed on the side of the first material layer 2 away from the base 1. The second material layer 3 may cover the first material layer 2.

Optionally, the second material layer 3 may be disposed in the same layer as the anode layer of the sub-pixel, that is, the second material layer 3 and the anode layer of the sub-pixel are prepared from the same material by the same patterning process. The manufacturing process of the second material layer 3 and the anode layer may include: forming a second material film on the side of the first material layer 2 away from the base 1, and patterning the second material film to acquire the second material layer and the anode layer.

Optionally, the second material film may be formed through the sputtering process, and the second material film may be etched through the dry etching.

Covering the first material layer 2 by the second material layer 3 refers to that the second material layer 3 covers the first portion 21 and the plurality of second portions 22 of the first material layer 2, and the second material layer 3 can fill the target region.

The second material layer 3 is in contact with not only the side of the second portion 22 close to the second material layer 3 and the side of the first portion 21 close to the second material layer 3, but also the sidewall of the second portion 22. Therefore, the contact area and the bonding force between the first material layer 2 and the second material layer 3 are increased, so that the first material layer 2 and the second material layer 3 are not easily peeled off. Further, the water and oxygen path can be prevented from forming at the interface between the first material layer 2 and the second material layer 3, thereby preventing grow dark spots from generating on the display substrate, and ensuring the display effect of the display device.

In step S24, a third material layer is formed on a side of the second material layer away from the first material layer.

In the embodiment of the present disclosure, after the second material layer 3 is formed, the third material layer 5 may be formed on the side of the second material layer away from the first material layer 2. The third material layer 5 may be in contact with the second material layer 3.

Optionally, the first material layer 2 and the second material layer 3 may form a common ground terminal voltage circuit trace of the display substrate. The first material layer 2 and the second material layer 3 may serve as the common ground terminal voltage circuit traces to provide common ground terminal voltage signals for the third material layer 5 (the cathode layer of the sub-pixel).

In step S25, an encapsulation film layer is formed on a side of the third material layer away from the second material layer.

In the embodiment of the present disclosure, after the third material layer 5 is formed, the encapsulation film layer 6 may be formed on the side of the third material layer 5 away from the second material layer 3. The encapsulation film layer 6 may be configured to encapsulate the display region of the display substrate to prevent water vapor from entering the display region, so as to ensure the encapsulation performance of the display substrate.

In summary, the embodiment of the present disclosure provides a method for manufacturing a display substrate. The thickness of the first portion of the first material layer in the non-display region of the display substrate manufactured by the method is less than the thickness of the second portion, so that the second material layer is in contact with the sidewall of the second portion. Therefore, the contact area and the bonding force between the second material layer and the first material layer can be increased, and the first material layer and the second material layer are prevented from peeling off. Further, the water and oxygen path is prevented from forming at the interface between the first material layer and the second material layer, thereby preventing grow dark spots from generating on the display substrate, and ensuring the yield and display effect of the display device.

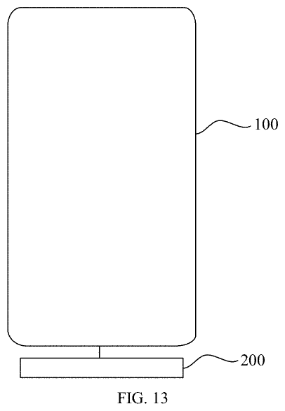

FIG. 13 is a schematic structural diagram of a display device according to an embodiment of the present disclosure. Referring to FIG. 13, the display device may include a power supply component and a display substrate connected to the power supply component. The display substrate may be the display substrate 100 in the above embodiment. The power supply component 200 may be configured to supply power to the display substrate 100.

Optionally, the display substrate may be an OLED display substrate or a quantum dot light emitting diode (QLED) display substrate. That is, the display device includes, but is not limited to, the OLED display substrate, the QLED display substrate, and the like.

In addition, the display device may be a curved display device, a flexible display device, or a stretchable display device. The specific product type of the display device is not limited, and display device may be, for example, a mobile phone, a tablet computer, a display, a television, a painting screen, an advertising screen, electronic paper, a smart wearable device, a vehicle navigation device, and so on.

Since the display substrate has good encapsulation performance and long service life, the display device also has good product quality.

It should be noted that the relational terms such as “first” and “second” as used herein are merely used to distinguish a subject or an operation from another subject or operation, instead of requiring or implying any substantial relation or order between these subjects or operations. Moreover, the terms “include”, “comprise” or any variations thereof are intended to cover a nonexclusive inclusion, such that a process, a method, an item or a device including a series of elements not only includes these elements, but also includes other elements that are not set forth specifically, or also includes an inherent element of such a process, method, item or device. Without more limitations, the element defined by the phrase “including a . . . ” does not exclude the existence of other same elements in the process, method, item, or device that including such element.

Described above are merely optional embodiments of the present disclosure, and are not intended to limit the present disclosure. Within the spirit and principles of the disclosure, any modifications, equivalent substitutions, improvements, and the like are within the protection scope of the present disclosure.

What is claimed is:

1. A display substrate, comprising a display region and a non-display region surrounding the display region, wherein a portion, in the non-display region, of the display substrate comprises:
a base;
a first material layer disposed on a side of the base, wherein the first material layer comprises a first portion and a plurality of second portions, a thickness of the first portion being less than a thickness of the second portion, and the first portion being disposed between any adjacent two second portions; and
a second material layer disposed on a side of the first material layer away from the base, wherein the second material layer covers the first material layer.

2. The display substrate according to claim 1, wherein the thickness of the first portion is 0.

3. The display substrate according to claim 1, wherein materials of the first material layer and the second material layer are both conductive materials.

4. The display substrate according to claim 3, wherein
the first material layer and a gate of a thin film transistor of a sub-pixel, in the display region, of the display substrate are disposed in a same layer; and
the second material layer and an anode of the sub-pixel, in the display region, of the display substrate are disposed in a same layer.

5. The display substrate according to claim 3, wherein
the first material layer and a source-drain of a thin film transistor of a sub-pixel, in the display region, of the display substrate are disposed in a same layer; and
the second material layer and an anode of the sub-pixel, in the display region, of the display substrate are disposed in a same layer.

6. The display substrate according to claim 1, wherein a common ground terminal voltage circuit trace, in the non-display region, of the display substrate comprises the first material layer and the second material layer.

7. The display substrate according to claim 1, wherein the first material layer comprises a titanium layer, an aluminum layer, and another titanium layer which are sequentially laminated in a direction going away from the base.

8. The display substrate according to claim 1, wherein the first material layer comprises a molybdenum layer, an aluminum layer, and another molybdenum layer which are sequentially laminated in a direction going away from the base.

9. The display substrate according to claim 1, wherein a surface of the second material layer away from the first material layer is parallel to a bearing surface of the base.

10. The display substrate according to claim 1, wherein a shape of an orthographic projection of the second portion on the base is a rectangle.

11. The display substrate according to claim 1, wherein orthographic projections of the plurality of second portions on the base are uniformly arranged in an array.

12. The display substrate according to claim 1, wherein the plurality of second portions are uniformly arranged sequentially in a target direction, the target direction being a pixel row direction or a pixel column direction of the display substrate.

13. The display substrate according to claim 1, wherein for each of the second portions, an area of an orthographic projection of a surface, away from the base, of the second portion on the base is less than an area of an orthographic projection of a surface, close to the base, of the second portion on the base.

14. The display substrate according to claim 13, wherein the orthographic projection of the surface, away from the base, of the second portion on the base is within the orthographic projection of the surface, close to the base, of the second portion on the base.

15. The display substrate according to claim 1, further comprising: a third material layer and an encapsulation film layer which are disposed on a side of the second material layer away from the first material layer.

16. The display substrate according to claim 15, wherein the third material layer is a cathode layer of a sub-pixel of the display substrate.

17. A method for manufacturing a display substrate, wherein the display substrate comprises a display region and a non-display region surrounding the display region, the method comprising:
forming a first material layer on a side of a base, wherein the first material layer comprises a first portion and a plurality of second portions, a thickness of the first portion being less than a thickness of the second portion, and the first portion being disposed between any adjacent two second portions; and
forming a second material layer on a side of the first material layer away from the base, wherein the second material layer covers the first material layer.

18. The method according to claim 17, wherein forming the first material layer on the side of the base comprises:
forming a first material film on the side of the base; and
patterning the first material film to obtain the first material layer.

19. The method according to claim 17, wherein the thickness of the first portion is 0.

20. A display device, comprising a power supply component and a display substrate connected to the power supply component, wherein the power supply component is configured to supply power to the display substrate; and the display substrate comprises a display region and a non-display region surrounding the display region, and a portion, in the non-display region, of the display substrate comprises:
a base;
a first material layer disposed on a side of the base, wherein the first material layer comprises a first portion and a plurality of second portions, a thickness of the first portion being less than a thickness of the second portion, and the first portion being disposed between any adjacent two second portions; and
a second material layer disposed on a side of the first material layer away from the base, wherein the second material layer covers the first material layer.
